(19) United States
(12) Patent Application Publication
(10) Pub. No.: US 2011/0284926 A1
(43) Pub. Date: Nov. 24, 2011

(54) AVALANCHE PHOTODIODE STRUCTURE

(75) Inventor: Ching Kean Chia, Singapore (SG)

(73) Assignee: AGENCY FOR SCIENCE, TECHNOLOGY AND RESEARCH, Singapore (SG)

(21) Appl. No.: 13/110,857

(22) Filed: May 18, 2011

Related U.S. Application Data
(60) Provisional application No. 61/395,887, filed on May 18, 2010.

(51) Int. Cl. H01L 31/107; H01L 31/18

(52) U.S. Cl. 257/186; 438/91; 257/E31.064; 257/E31.116

(57) ABSTRACT

An avalanche photodiode structure, to a method of fabricating an avalanche photodiode structure, and to devices incorporating an avalanche photodiode structure. The avalanche photodiode structure comprises a Ge doped region having a first polarity; a GaAs doped region having a second polarity opposite to the first polarity; and an undoped region between the Ge doped region and the GaAs doped region forming a heterojunction; wherein the undoped region comprises Ge and AlₓGa₁₋ₓAs.

### CROSS-REFERENCE(S) TO RELATED APPLICATION(S)

This application claims the benefit, under 25 U.S.C. §119(e), of U.S. Provisional Application No. 61/395,887, filed May 18, 2010, which is hereby incorporated by reference in the present disclosure in its entirety.

### BACKGROUND

1. Field

This invention relates broadly to an avalanche photodiode structure, to a method of fabricating an avalanche photodiode structure, and to devices incorporating an avalanche photodiode structure. In particular, embodiments of the present invention relate to a bandgap engineered low noise Ge—AlₓGa₁₋ₓAs heterojunction avalanche photodiode structure.

2. Description of Related Art

Avalanche photodiodes (APDs) are used to convert optical signal to electrical signal and at the same time provide internal gain (amplification of the electrical signal) via an impact ionization process. Avalanche multiplication in APD enables the APD to be used in low light level applications, for example, in active optical cables (AOCs) with light signals in the range of microwatts, and helps to compensate for the signal losses in the conventional optical fiber communication systems. In contrast, pin photodiodes with unity multiplication factor require external pre-amplifiers to strengthen the signal.

Low noise in APDs can be obtained if one type of carrier has a significantly larger ionization coefficient (α for electrons and β for holes) than the other. Si was found to exhibit large α/β ratio and hence produces low multiplication (excess) noise. High speed and high capacity optical fiber telecommunication systems need to operate at long wavelengths because of their low fiber attenuation (wavelength, λ=1550 nm) and low chromatic dispersion (λ=1310 nm). The emerging AOC and optical interconnect market requires detection at 850 and 1310 nm. Unfortunately, existing Si homojunction detectors do not respond at wavelengths>1100 nm, and Ge homojunction detectors were found to suffer from an intolerably high amplification noise. Stimulated by market demand a considerable amount of work has been carried out in APD research since the development of these telecommunication systems. In seeking an alternative, III-V compound semiconductors have received much attention. However, most semiconductors have nearly equal ionization coefficients.

A need therefore exists to provide an avalanche photodiode, a method of fabricating an avalanche photodiode, and devices incorporating an avalanche photodiode that seek to address at least one of the above mentioned problems.

### BRIEF SUMMARY

According to a first aspect of the present invention there is provided an avalanche photodiode structure comprising a Ge doped region having a first polarity; a GaAs doped region having a second polarity opposite to the first polarity; and an undoped region between the Ge doped region and the GaAs doped region forming a heterojunction; wherein the undoped region comprises Ge and AlₓGa₁₋ₓAs.

The undoped region may comprise Ge, GaAs and AlₓGa₁₋ₓAs.

The undoped region may comprise a GaAs—AlₓGa₁₋ₓAs graded composition portion.

The GaAs—AlₓGa₁₋ₓAs graded composition portion may extend between a Ge layer of the undoped region and a AlₓGa₁₋ₓAs layer of the undoped region.

The GaAs—AlxGa1-xAs graded composition portion may extend between a Ge layer of the undoped region and a AlₓGa₁₋ₓAs portion of the GaAs doped region.

The GaAs doped region may comprise an n-type light absorption layer for 850 nm and the Ge doped region comprises a p-type absorption layer for 1310 and 1550 nm.

The heterojunction may have a p-i-n configuration disposed on one of a group consisting of a Ge p-type substrate, a GaAs n-type substrate, a Ge-on-insulator p-type substrate or GaAs-on-insulator n-type substrate.

The undoped region may be smaller than 0.3 μm thick.

The undoped region may be smaller than 0.2 μm thick.

In example embodiments, 1≧x≧0.2, preferably 1≧x≧0.4.

An AlₓGa₁₋ₓAs undoped layer thickness (t_{AlxGa1-xAs}) may be greater than an Ge undoped layer thickness (t_{Ge}).

An AlₓGa₁₋ₓAs undoped layer thickness (t_{AlxGa1-xA})ₛ may be greater than a combined thickness of a Ge undoped layer and a GaAs undoped layer (t_{Ge}+t_{GaAs}).

An AlₓGa₁₋ₓAs undoped layer thickness (t_{AlxGa1-xA}) may be greater than a combined thickness of a Ge undoped layer plus a GaAs—AlₓGa₁₋ₓAs undoped graded layer (t_{Ge}+t_{GaAs—AlGaAs}).

An GaAs—AlₓGa₁₋ₓAs undoped graded composition layer thickness (t_{GaAs—AlxGa1-xAs}) may be greater than a Ge undoped layer thickness (t_{Ge}).

The avalanche photodiode structure may have a detection range covering about 400-1700 nm wavelength.

The GaAs doped region may comprise a graded AlₓGa₁₋ₓAs/GaAs n+ layer at an undoped-n+ interface.

The avalanche photodiode structure may further comprise ohmic contacts for the Ge doped region and the GaAs doped region respectively.

The ohmic contacts to the Ge doped region and the GaAs doped region respectively may be formed from substantially the same material.

A GaAs layer interfacing to a Ge layer of the undoped region may comprise indium.

The GaAs layer interfacing to the Ge layer of the undoped region may comprise 1% indium (In_{0.01}Ga_{0.99}As).

According to a second aspect of the present invention there is provided device comprising an avalanche photodiode structure as defined in the first aspect.

According to a third aspect of the present invention there is provided method of fabricating an avalanche photodiode structure, the method comprising the steps of providing a Ge doped region having a first polarity; providing a GaAs doped region having a second polarity opposite to the first polarity; and providing an undoped region between the Ge doped region and the GaAs doped region forming a heterojunction; wherein the undoped region comprises Ge and AlₓGa₁₋ₓAs.

The method may further comprise forming ohmic contacts to the Ge doped region and the GaAs doped region respectively from substantially the same material.

### DESCRIPTION OF THE FIGURES

FIG. 1 shows the (A) structure and (B) band-edge profile under reverse bias of Ge—AlₓGa₁₋ₓAs—GaAs photodiodes of example embodiments.

FIG. 2 shows the (A) structure and (B) band-edge profile under reverse bias of Ge—GaAs—AlₓGa₁₋ₓAs—GaAs photodiodes of example embodiments. GaAs is incorporated to allow electrons to surmount the potential barrier at the heterointerface.

FIG. 3 shows the (A) structure and (B) band-edge profile under reverse bias of Ge—(GaAs—AlₓGa₁₋ₓAs)—AlₓGa₁₋ₓAs—GaAs photodiodes, with a graded composition of GaAs—AlₓGa₁₋ₓAs layer, of example embodiments. The graded composition GaAs—AlₓGa₁₋ₓAs layer prevents electron trapping.

FIG. 4 shows the (A) structure and (B) band-edge profile under reverse bias of Ge—(GaAs—AlₓGa₁₋ₓAs)—GaAs photodiodes, with a graded composition of GaAs—AlₓGa₁₋ₓAs layer, of example embodiments.

FIG. 5 (A) to (L) show schematically the fabrication process for the avalanche photodiodes of example embodiments.

FIG. 6 shows the simulated ionization coefficients in bulk Ge, GaAs, Al_{0.3}Ga_{0.7}As and Al_{0.8}Ga_{0.2}As. Lines represent the experimental data and symbols represent the simulated results. Solid and dotted lines (solid and opened symbols) represent electrons and holes, respectively.

FIG. 7 shows the valance band-edge discontinuity at the Ge—GaAs interface determined by the XPS method.

FIG. 8 shows the device configurations for Ge—AlₓGa₁₋ₓAs heterogeneous structures of example embodiments: (A) p-type Ge— no holes trapping effect and (B) n-type Ge— holes trapping expected at the Ge—AlₓGa₁₋ₓAs heterointerface.

FIG. 9 shows the simulated electron (Mₑ) and hole (Mₕ) multiplication characteristics in Ge homojunction, AlₓGa₁₋ₓAs (x=0.45 and 0.60) homojunctions, and Ge—AlₓGa₁₋ₓAs heterojunctions with the same thickness. Large difference in Mₑ and Mₕ is observed in the (A) Ge—Al_{0.45}Ga_{0.55}As and (B) Ge—Al_{0.6}Ga_{0.4}As heterojunctions.

FIG. 10 shows the ionization coefficients in Ge—AlₓGa₁₋ₓAs heterojunctions in comparison with their homojunction counterparts and Si, at (A) x=0.45, (B) x=0.60. The corresponding ionization ratios are shown in (C).

FIG. 11(A) shows the position dependent ionization coefficients in a 0.1 μm thick GaAs homojunction pin (at reverse bias of 5V, multiplication=1.69 and 7.2V, multiplication=38.45).

FIG. 11(B) shows the position dependent ionization coefficients in a 0.1 μm thick Ge homojunction pin (at reverse bias of 3.5V, multiplication=1.83 and 5V, multiplication=28.15).

FIG. 11(C) shows the position dependent ionization coefficients in a 0.1 μm thick Ge/GaAs heterojunction pin in 50-50 thickness ratio.

FIG. 11(D) shows the position dependent ionization coefficients in a 0.1 μm thick Ge/GaAs heterojunction pin in 10-90 thickness ratio (at reverse bias of 5.8V, multiplication=13.2).

FIG. 11(E) shows the position dependent ionization coefficients in a 0.1 μm thick Ge/Al_{0.6}Ga_{0.4}As heterojunction in 50-50 thickness ratio.

FIG. 11(F) shows the position dependent ionization coefficients in a 0.1 μm thick Ge/Al_{0.45}Ga_{0.55}As heterojunction in 30-70 thickness ratio.

FIG. 11(G) shows the position dependent ionization coefficients in a 0.1 μm thick Ge/Al_{0.6}Ga_{0.4}As heterojunction in 30-70 thickness ratio.

FIG. 11(H) shows the position dependent ionization coefficients in a 0.1 μm thick Ge/Al_{0.6}Ga_{0.4}As heterojunction in 10-90 thickness ratio.

FIG. 11(I) shows the position dependent ionization coefficients in a 0.1 μm thick Ge/Al_{0.8}Ga_{0.2}As heterojunction in 30-70 thickness ratio.

FIG. 11 (J) shows the position dependent ionization coefficients in a 0.1 μm thick Ge/Al_{0.8}Ga_{0.2}As heterojunction in 10-90 thickness ratio.

### DETAILED DESCRIPTION

The following description is presented to enable a person of ordinary skill in the art to make and use the various embodiments. Descriptions of specific devices, techniques, and applications are provided only as examples. Various modifications to the examples described herein will be readily apparent to those of ordinary skill in the art, and the general principles defined herein may be applied to other examples and applications without departing from the spirit and scope of the various embodiments. Thus, the various embodiments are not intended to be limited to the examples described herein and shown, but are to be accorded the scope consistent with the claims.

Example embodiments of the present invention provide a bandgap engineered low noise Ge—AlₓGa₁₋ₓAs heterojunction avalanche photodiode (APD) with a large difference in the electron and hole ionization coefficients. The heterojunction APD can be used for a wide detection range of 400 nm-1600 nm, with low excess noise, at 850, 1310 and 1550 nm, owing to the suppressed ionization of the opposite carrier and dead space effects.

It has been found by the inventors that an enhanced difference in the hole and electron multiplication factors respectively can be realized due to the incorporation of a Ge layer in the undoped region of heterojunction APDs in example embodiments.

Example embodiments of the present invention incorporate an AlₓGa₁₋ₓAs layer into the undoped region to suppress the device leakage current, and at the same time enhance the difference in the electron and hole impact ionization coefficients in the heterojunction APD.

In one example embodiments of the present invention, a device structure with a n(GaAs/AlₓGa₁₋ₓAs)-i(AlₓGa₁₋ₓAs/GaAs/Ge)-p(Ge) configuration is provided, thereby preferably minimizing carrier trapping issues.

Example embodiments of the present invention advantageously suppress the feedback of electron ionization in the heterojunction APD, thereby reducing the overall carrier transit time and increasing the operation speed.

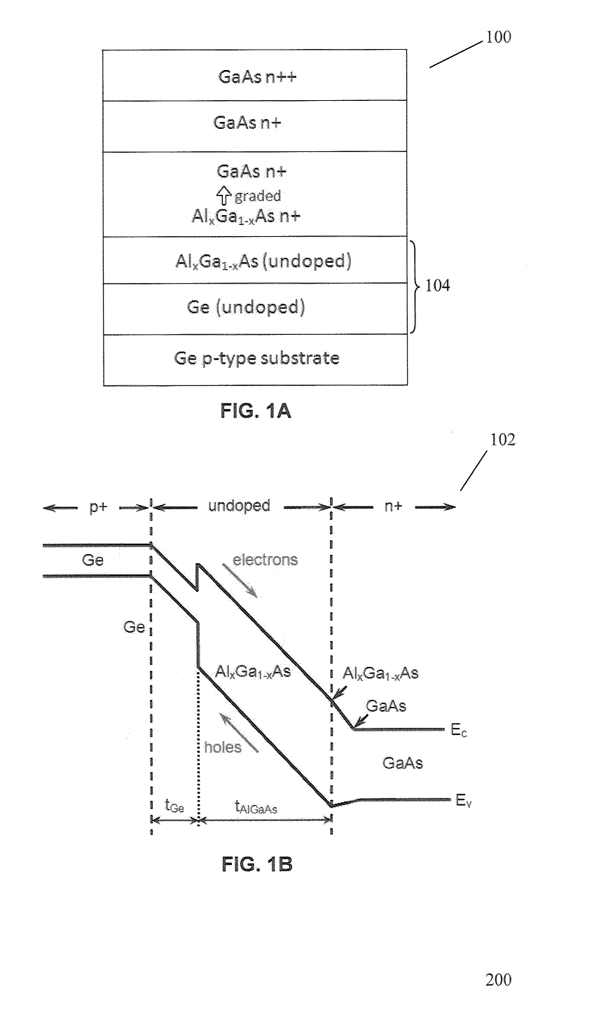

FIGS. 1 to 4 show the structures and band-edge profiles under reverse bias for avalanche photodiodes of example embodiments of the present invention. For illustration and clarity purposes, separate layers are shown for the different compositions. It should be appreciated that distinct interfaces may not necessarily be present from a composition to another composition, for example when there is a graded composition.

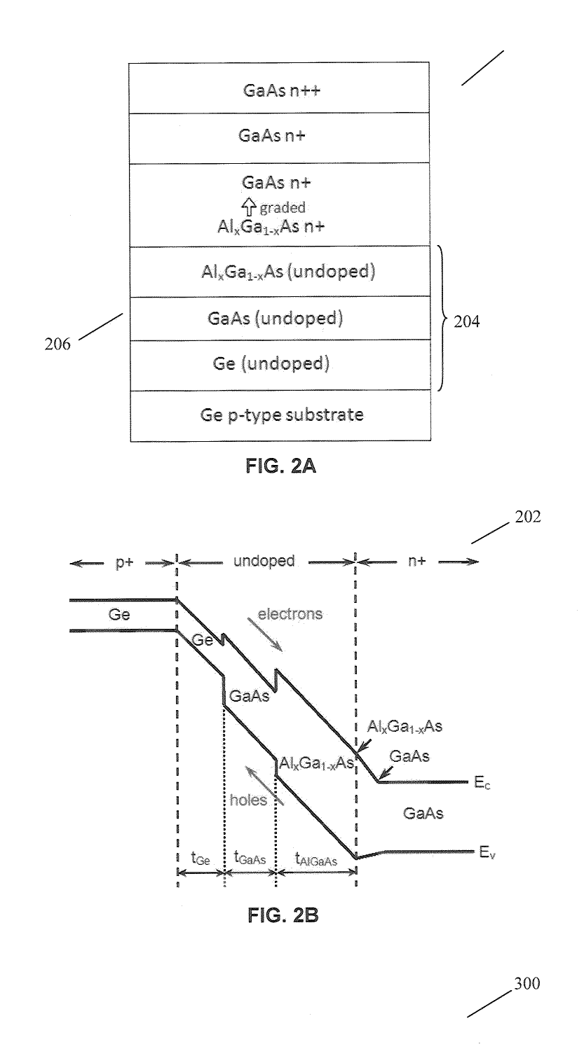

FIGS. 1(A) and (B) show the structure 100 and band-edge profile 102 under reverse bias of a Ge—AlₓGa₁₋ₓAs—GaAs undoped region 104 heterojunction photodiode of an example embodiment. FIGS. 2(A) and (B) show the structure 200 and band-edge profile 202 under reverse bias of a Ge—GaAs—AlₓGa₁₋ₓAs—GaAs undoped region 204 heterojunction photodiode of another example embodiment. GaAs 206 is incorporated into the structure 200 to allow electrons to surmount the potential barrier at the heterointerface.

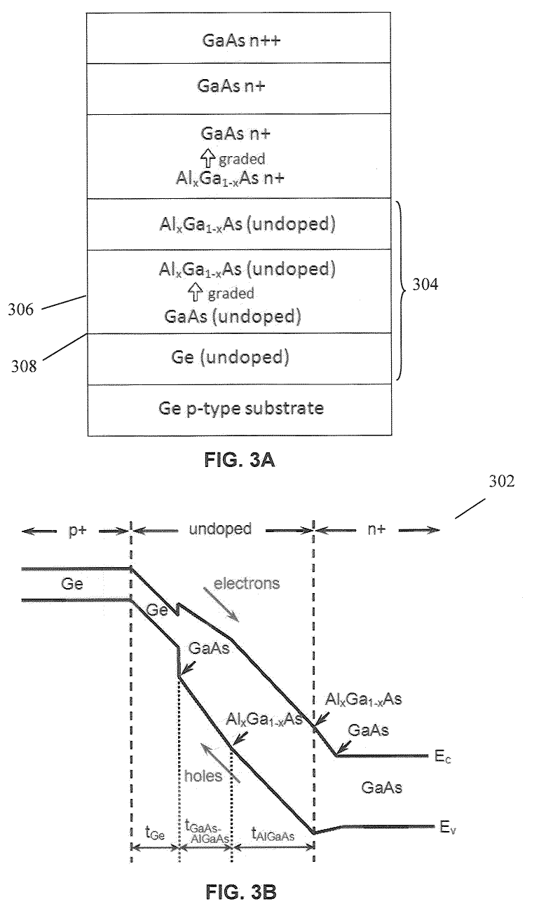

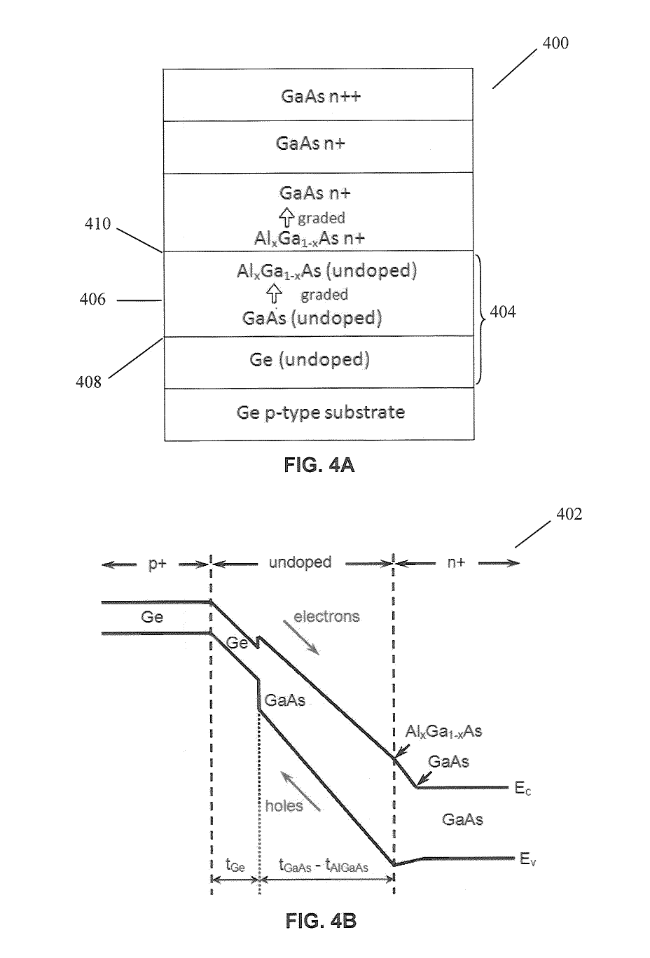

FIGS. 3(A) and (B) show the structure 300 and band-edge profile 302 under reverse bias of a Ge—(GaAs—AlₓGa₁₋ₓAs)—AlₓGa₁₋ₓAs—GaAs undoped region 304 heterojunction photodiode of another example embodiment. FIGS. 4(A) and (B) show the structure 400 and band-edge profile 402 under reverse bias of a Ge—(GaAs—AlₓGa₁₋ₓAs)—GaAs undoped region 404 heterojunction photodiode of another example embodiment. The structures shown in FIGS. 3 and 4 incorporate graded composition GaAs—AlₓGa₁₋ₓAs layers 306, 406 within the undoped regions 304, 404, which advantageously prevents electron trapping. In the structure of FIG. 3, the GaAs to AlₓGa₁₋ₓAs composition grading extends from the Ge—GaAs interface 308 to about the middle of the undoped region 304, with the remaining undoped region 304 comprising AlₓGa₁₋ₓAs. In the structure of FIG. 4, the GaAs to AlₓGa₁₋ₓAs composition grading extends from the Ge—GaAs interface 408 to a graded AlₓGa₁₋ₓAs-(n+) region interface 410.

In example embodiments, x is preferably in the range 1≧x≧0.2, and more preferably x is in the range 1≧x≧0.4.

The undoped region of example embodiments is preferably <0.3 μm thick, and more preferably <0.2 μm thick.

In the example embodiment of FIG. 1, the thickness of the AlₓGa₁₋ₓAs portion of the undoped layer (t_{AlxGa1-xAs})>the thickness of the Ge portion of the undoped layer (t_{Ge}). In the example embodiment of FIG. 2, (t_{AlxGa1-xAs})>the combined thickness of the Ge portion and the GaAs portion of the undoped layer (t_{Ge}+t_{GaAs}). In the example embodiments of FIGS. 3 and 4, (t_{AlxGa1-xAs})>the combined thickness of the Ge portion and the GaAs—AlₓGa₁₋ₓAs graded layer portion of the undoped region (t_{Ge}+t_{GaAs—AlxGa1-xAs}), and (t_{GaAs—AlxGa1-xAs})>(t_{Ge}).

In example embodiments, indium can be added into the GaAs layers interfacing to the Ge layer of the undoped region for a better lattice matching with Ge, for example about 1% (In_{0.01}Ga_{0.99}As).

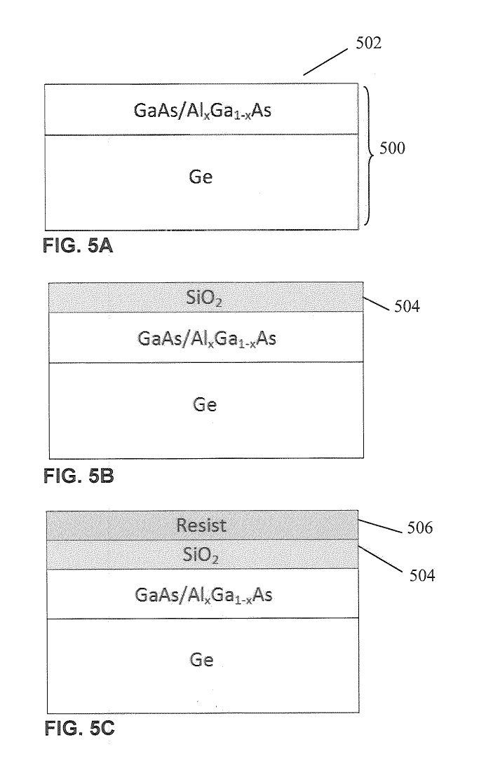

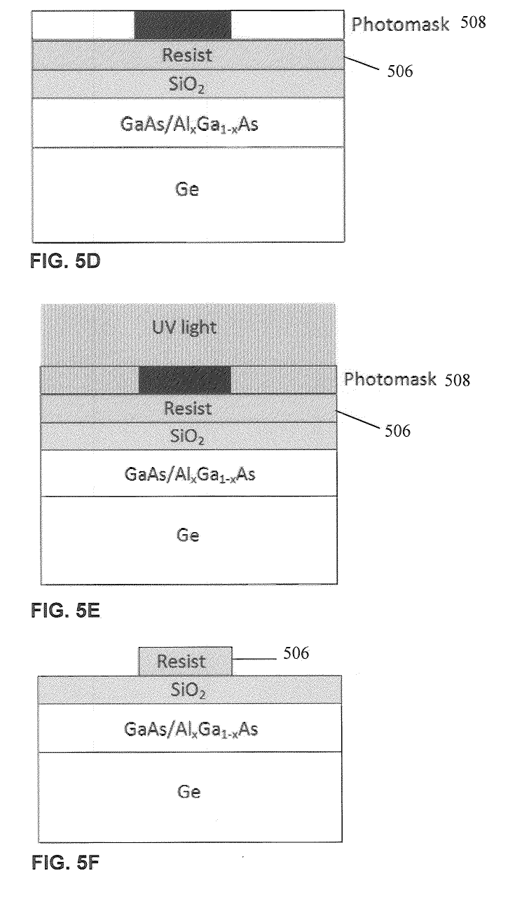

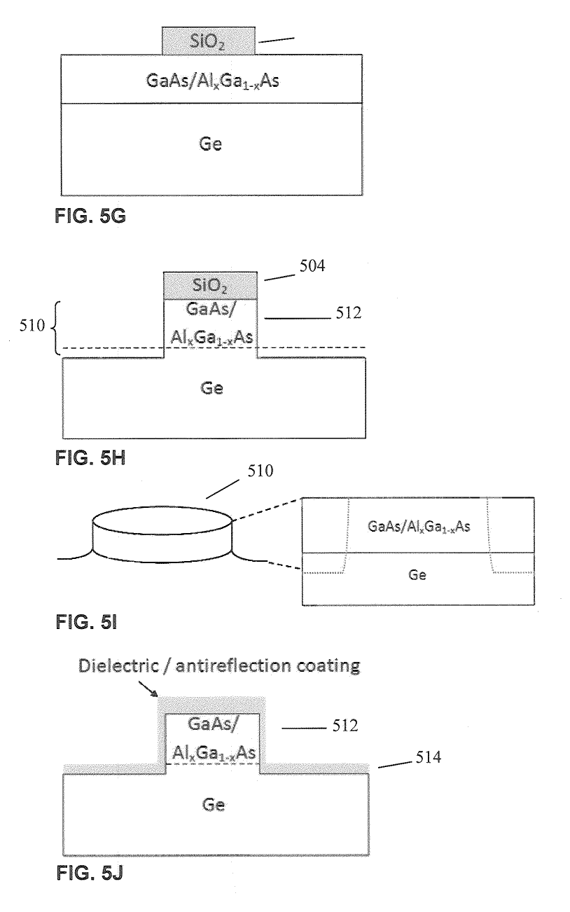

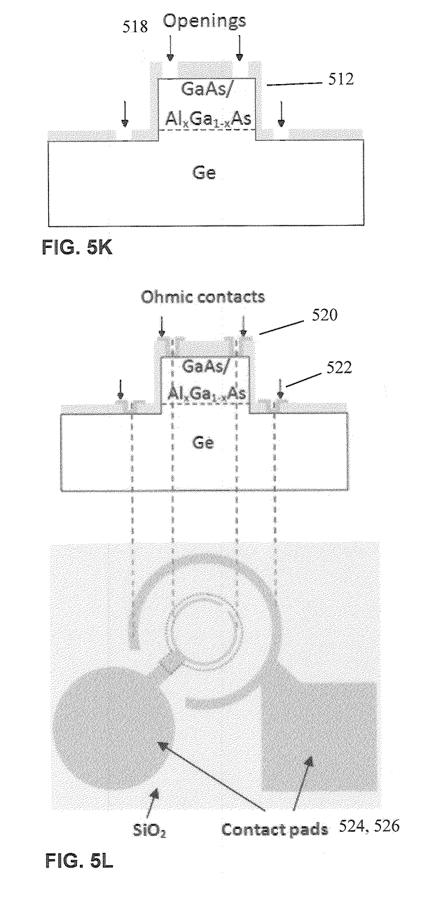

FIGS. 5(A) to (L) show the fabrication process for avalanche photodiodes (APD) according to an example embodiment. The APDs can be fabricated using for example a standard photolithography process, as disclosed below.

FIG. 5(A) Wafer cleaning

A Ge—GaAs heterojunction structure 500 is provided. The heterojunction structure can for example be in the forms described above with reference to FIGS. 1 to 4. The heterojunction structure 500 can be fabricated using known techniques including but not limited to Molecular-Beam Epitaxy (MBE), Metal-Organic Chemical Vapor Deposition (MOCVD), Pulsed Laser Deposition (PLD), Liquid Phase Epitaxy (LPE), Chemical Vapor Deposition (CVD), sputtering and combinations thereof.) The sample surface 502 is cleaned using chemical solutions. For example, first, the sample surface 502 is cleaned using acetone for about 3 minutes in an ultrasonic bath, and then repeated using methanol and isopropyl alcohol (IPA). The sample surface 502 is rinsed in deionised (DI) water for about 1 minute and blown dry using a N₂ gun.

FIG. 5(B) Depositing SiO2 film using PECVD

A dielectric film 504 (for example SiO₂) with a thickness of about 200-400 nm is deposited using plasma-enhanced chemical vapor deposition (PECVD).

FIG. 5(C) Spin coating photoresist (PR)

A resist 506 is applied to the surface of the dielectric layer 504 using e.g. a spin-coating machine. The resist 506 is then pre-baked, where the sample is gently heated in a convection oven and then on a hotplate to evaporate the resist solvent and to partially solidify the resist 506.

FIGS. 5(D) to (F) Transferring the APD photomask pattern

The photomask 508 is brought into contact or in proximity contact with the resist 506. During a UV exposure process, the positive resist 506 undergoes a chemical reaction and leaves a negative image of the mask 508 pattern after being immersed in a developer. The sample can undergo a post-bake process to further harden the resist 506 and to remove any residue of the developer.

FIG. 5(G) Transferring PR pattern onto SiO2

Using a wet chemical etch, e.g. a buffered hydrofluoric (BHF) etch, the dielectric layer 504 is selectively removed. The remaining resist is then removed using a resist solvent.

FIG. 5(H) Forming mesa diodes

The dielectric layer 504 pattern is used as a hard mask for etching of the semiconductor materials 510 to form mesa structures 512. This can be done using dry etching, e.g. inductively coupled plasma (ICP) etching, or wet (chemical) etching. After the mesa structures 512 have been formed, the dielectric layer 504 is removed, FIG. 5(I).

FIG. 5(J) Dielectric and/or antireflection coating

A dielectric (eg. SiO₂ or SiNₓ) film and/or an antireflection coating (eg. SiO₂/SiNₓ), indicated at numeral 514, are then deposited using PECVD for isolation and to minimize the light reflection at the wavelengths of interest.

FIGS. 5(K) to (L) Contact windows opening

Using a photomask (not shown) designed for contact windows, patterns for metal contacts on the mesa structures 512 can be formed by repeating the patterning steps as described above with reference to FIGS. 5(C) to (G). Openings 518 for the ohmic contacts can be formed together for n- (on top of the mesa 512) and p- (at the side of the mesa 512) type contacts in example embodiments of the present invention. Both p-type and n-type ohmic contacts can be formed at the same time because the same ohmic contact recipe for n-type GaAs ohmic contact can be used for p-type Ge ohmic contact. Conventionally, the ohmic contacts for n-type and p-type need to be formed separately for homojunction photodiodes, where additional processing steps are required.

In order to form and isolate the p- and n-type contacts 520, 522, a photomask for lift off is used by repeating the photoresist patterning steps as described above with reference to FIGS. 5(C) to (F). The resist (not shown) is then removed in a solvent after contact metallization using for example e-beam metallization, leaving the p- and n-type contacts 520, 522 in isolation as illustrated in FIG. 5(L), which shows the cross-sectional and top views of the final fabricated device of example embodiments. The contact pads 524, 526 design and position can be altered according to specific requirements. A rapid thermal annealing process can then be performed to minimize the contact resistance.

The characteristics of the APDs according to example embodiment are demonstrated in the following using a Monte Carlo (MC) simulation program.

The MC method has been used widely in semiconductor device simulation to study hot carrier motion in a crystal under the influence of an applied electric field and subject to scattering processes according to given probabilities describing the microscopic scattering mechanisms [Chen Shiyu, Xu Kunyuan, and Wang Gang, “Monte Carlo Investigation of Size-Dependent Impact Ionization Properties in InP Under Submicron Scale”, Journal of Lightwave Technology, Vol. 27, No. 10, May 15 (2009)]. The method relies on the generation of random numbers to determine the occurrence of random events such as the termination of a carrier's free flight, selection of a scattering event, the change in flight angle and in momentum. Essential fitting parameters in the program such as phonon scattering and impact ionization rates, are obtained by fitting to the experimental data for bulk materials, whereas ionization threshold energy Eₜₕ and phonon energy hw are obtained from the literature [Adachi S., “GaAs, AlAs, and AlₓGa₁₋ₓAs: Material parameters for use in research and device application”, J. Appl. Phys., 58, R1 (1985); Dargys A. and J. Kundrotas, “Handbook on Physical Properties of Ge, Si, GaAs and InP”, Vilnius, Science and Encyclopedia Publishers, (1994); Vorobyev L. E. Handbook Series on Semiconductor Parameters, vol. 1, M. Levinshtein, S. Rumyantsev and M. Shur, ed., World Scientific, London, pp. 33-57 (1996)].

The ionization rate Rᵢ at an energy E which exceeds the threshold energy, Eₜₕ, is described by a modified Keldysh expression, given as

Rᵢ=Cᵢ[(E/Eₜₕ)−1]³, (1)

where Cᵢ is a fitted scattering rate which includes the softness factor. A power 3 was used in this model after [Beattie A. R., “Impact ionisation rate and soft energy thresholds for anisotropic parabolic band structures”, Semicond. Sci. Technol., 3, 48 (1988)] to introduce additional softness in the impact ionization probability rate, accounting for the dependence of threshold energy on direction in k space. Eₜₕ is related to the band gaps of the material by the weighted average

$${E}_{th} = \frac{1}{8} [ {E}_{g}^{Γ} + 3 {E}_{g}^{X} + 4 {E}_{g}^{L} ] , \qquad ( 2 )$$

where E_{g}^{Γ}, E_{g}^{X} and E_{g}^{L} are the band gaps between the Γ, X and L-valleys and the valence band maximum at Γ. This expression for threshold energy was first used to predict the hydrostatic pressure dependence of breakdown in GaAs [Allam J., Adams A. R., Pate M. A. and Roberts J. S., “Impact ionisation in GaAs—distribution of final electron-states determined from hydrostatic-pressure measurements”, Appl. Phys. Lett., 67, 3304 (1995)] and was able to model accurately the breakdown voltages in many wide-gap III-V materials including AlₓGa₁₋ₓAs [Allam J., “Universal dependence of avalanche breakdown on bandstructure: Choosing materials for high-power devices”, Jpn. J. Appl. Phys., Part 1, 36, 1529 (1997).]. Ge was also found to follow the Brillouin-zone averaged energy gap in eq. (2) [Allam J. and Adams A. R.: “High Pressure Measurements and the “Universal” Scaling of Impact Ionization with Bandstructure”, phys. stat. sol. (b) 211, 335 (1999).].

The strength of phonon scattering for electrons and holes is obtained by fitting to the multiplication characteristics of the bulk structures and is represented by energy-independent phonon scattering mean free paths, λₑ and λₕ, respectively.

Table 1 summarizes the material parameters used in the simulation.

TABLE 1
Material parameters used in the simulation.

| | | | | Cᵢ | | |
|---|---|---|---|---|---|---|
| | | DOS mass | λₑ, λₕ | (×10¹³ | Eₜₕ | hω |
| Material | Particle | m^{DOS}/mₒ | (Å) | s⁻¹) | (eV) | (meV) |
| Ge | electron | 0.220 | 91 | 0.11 | 0.86 | 37.5 |
| | hole | 0.340 | 102 | | | |
| GaAs | electron | 0.607 | 51 | 1.20 | 1.75 | 29.0 |
| | hole | 0.530 | 46 | | | |
| Al_{0.3}Ga_{0.7}As | electron | 0.636 | 43 | 1.30 | 1.91 | 31.0 |
| | hole | 0.599 | 41 | | | |
| Al_{0.45}Ga_{0.55}As | electron | 0.651 | 40 | 1.35 | 1.99 | 32.5 |
| | hole | 0.634 | 38 | | | |
| Al_{0.6}Ga_{0.4}As | electron | 0.666 | 39 | 1.40 | 2.08 | 34.0 |
| | hole | 0.668 | 37 | | | |
| Al_{0.8}Ga_{0.2}As | electron | 0.686 | 39 | 1.65 | 2.21 | 35.0 |
| | hole | 0.714 | 34 | | | |

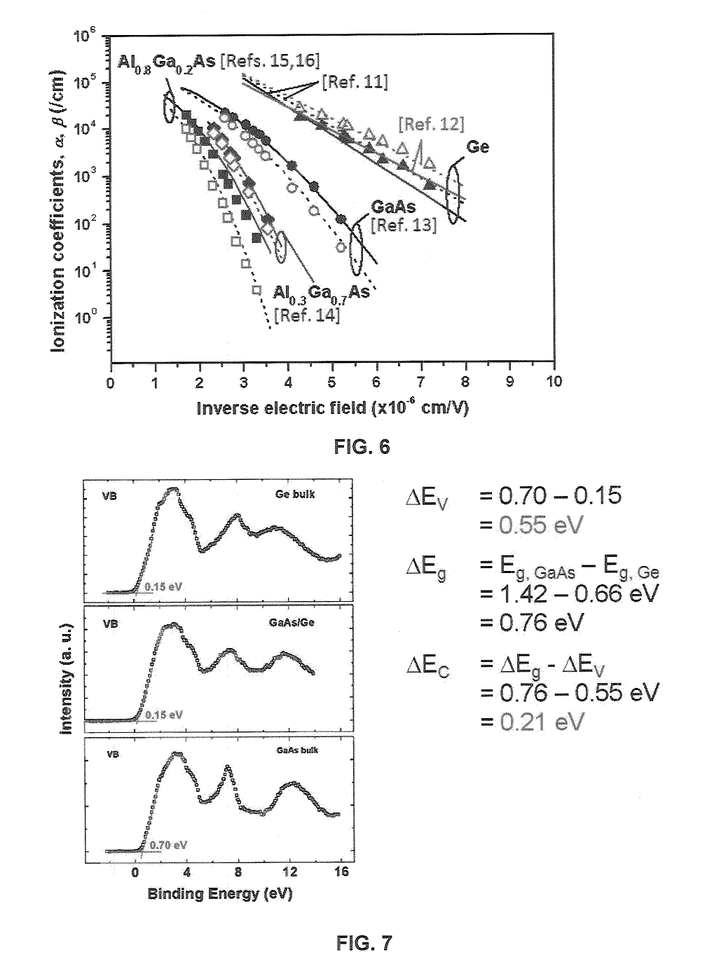

FIG. 6 shows the fitting of the ionization coefficients in Ge [Mikawa T., S. Kagawa, T. Kaneda, Y. Toyama, and O. Mikami, “Crystal orientation dependence of ionization rates in germanium”, Appl. Phys. Lett. 37, 4 387-389 (1980); Kyuregyan A. S, and S. N. Yurkov, “Room-temperature avalanche breakdown voltages of Si, Ge, SiC, GaAs, GaP and InP”, Sov. Phys. Semicond. 23, 10, 1126-1132 (1989)], GaAs [Bulman G. E., Robbins V. M. and Stillman G. E., “The determination of impact ionisation coefficients in (100) Gallium Arsenide using avalanche noise and photocurrent multiplication measurements”, IEEE Trans. Elec. Dev., 32, 2454 (1985).], Al_{0.3}Ga_{0.7}As [Robbins V. M., Smith S. C. and Stillman G. E., “Impact ionisation in AlₓGa₁₋ₓAs for x=0.1-0.4”, Appl. Phys. Lett., 52, 296 (1988)] and Al_{0.8}Ga_{0.2}As [B. K. Ng, J. P. R. David, S. A. Plimmer, M. Hopkinson, R. C. Tozer, and G. J. Rees, “Impact ionization coefficients of Al_{0.8}Ga_{0.2}As,”Appl. Phys. Len., vol. 77, no. 26, pp. 4374-4376, December (2000); B. K. Ng, J. P. R. David, G. J. Rees, R. C. Tozer, M. Hopkinson, and R. J. Airey, “Avalanche Multiplication and Breakdown in AlₓGa₁₋ₓAs (x<0.9)” IEEE Transactions on Electron Devices, Vol. 49, No. 12, Dec. (2002)], using the MC program.

For MC simulation in heterogeneous structures, the conduction (ΔE_{C}) and valence (ΔE_{V}) bandedge discontinuities of the Ge—GaAs interface were determined by the XPS technique, as shown in FIG. 7. Results are in close agreement with literature [Chamber S. A. and Irwin T. J., “Dopant incorporation, Fermi level movement, and band offset at Ge/GaAs (100) interface”, Physical Review B, 38, 7858-7861 (1988)]. The bandedge discontinuities of the GaAs—AlₓGa₁₋ₓAs interface are taken from literature since they are well reported, where ΔE_{C}=60% of ΔE_{g}, and ΔE_{V}=40% of ΔE_{g}.

Generally, the structure of the avalanche photodiodes of example embodiments can have the configurations comprising regions of (p-doped-undoped/intrinsic-n-doped) or (n-doped-undoped/intrinsic-p-doped), depending on the choice of materials and/or dopants. The undoped region is also known as the multiplication region, where multiplication occurs.

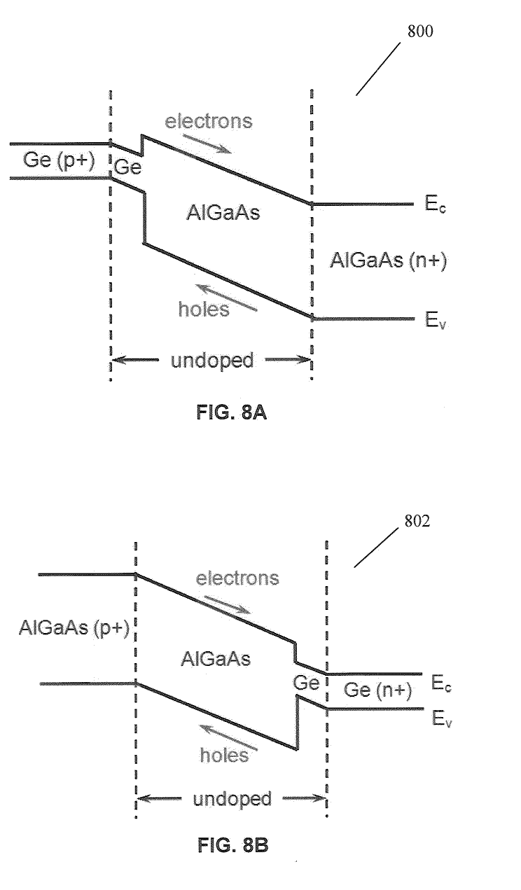

FIGS. 8(A) and 8(B) show the band-edge profiles 800, 802 of avalanche photodiodes of example embodiments of the present invention. FIG. 8(A) shows a n(AlₓGa₁₋ₓAs)-i(AlₓGa₁₋ₓAs/Ge)-p(Ge) (n-i-p) structure while FIG. 8(B) shows a p(AlₓGa₁₋ₓAs)-i(AlₓGa₁₋ₓAs/Ge)-n(Ge) (p-i-n) structure. The embodiment shown in FIG. 8(A) advantageously prevents carrier trapping effects, which may otherwise limit the device operation speed. It will be appreciated that the configuration in FIG. 8(A) may be generalized to a n(GaAs/AlₓGa₁₋ₓAs)-i(AlₓGa₁₋ₓAs/GaAs/Ge)-p(Ge) configuration.

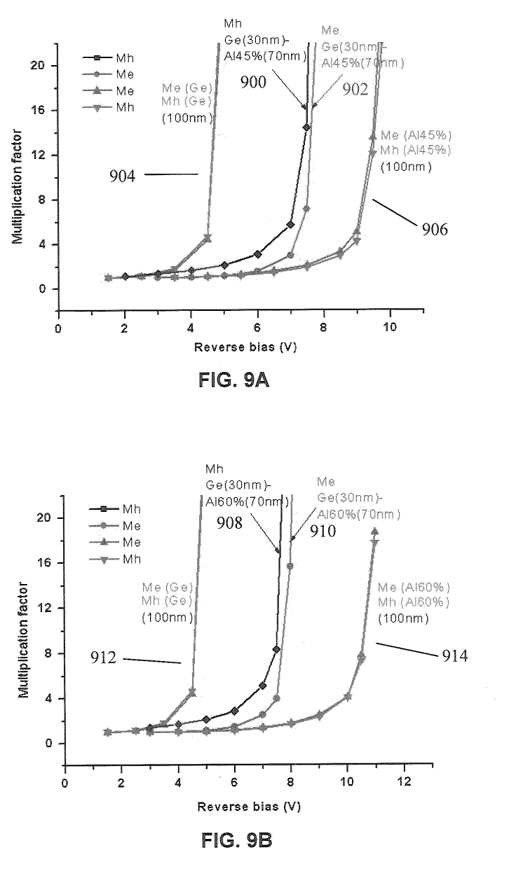

Monte Carlo simulations have been conducted for embodiments according to FIG. 8(A) with Al content x of 0, 0.3, 0.45, 0.6 and 0.8. All simulation results show advantageous significant reduction in feedback ionization in the AlₓGa₁₋ₓAs layer, with larger reduction in higher Al content AlₓGa₁₋ₓAs layer. For illustration, the results for Al contents of 0.45 and 0.60 are presented in FIGS. 9(A) and 9(B), respectively.

FIG. 9(A) shows the results of the electron and hole multiplication characteristics of the heterojunction structures of example embodiments of the present invention (curves 900, 902), in comparison with the homojunction counterparts (numerals 904, 906). The electrons and holes have a very large difference in the multiplication factor in the Ge—Al_{0.45}Ga_{0.55}As heterostructures of example embodiments.

FIG. 9(B) shows the results of the electron and hole multiplication characteristics of the heterojunction structures of example embodiments of the present invention (curves 908, 910), in comparison with the homojunction counterparts (numerals 912, 914). The electrons and holes have a very large difference in the multiplication factor in the Ge—Al_{0.6}Ga_{0.4}As heterostructures of example embodiments.

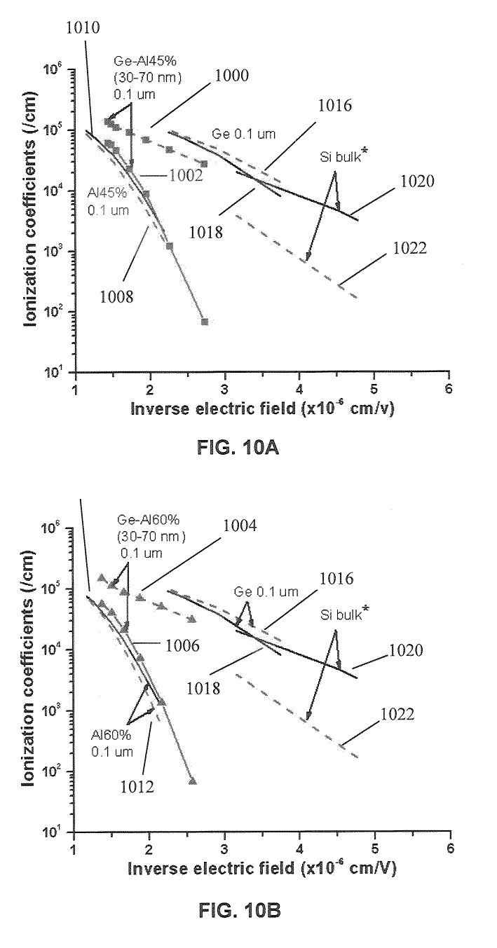

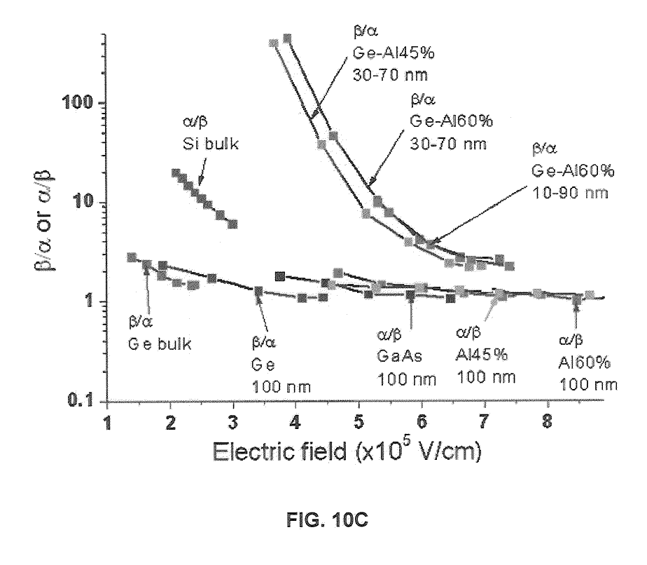

FIGS. 10(A) and 10(B), respectively, show the hole/electron ionization coefficients for Ge—Al_{0.45}Ga_{0.55}As (curves 1000, 1002) and Ge—Al_{0.6}Ga_{0.4}As heterojunctions (curves 1004, 1006), compared with same overall thickness Al_{0.45}Ga_{0.55}As (curves 1008, 1010), Al_{0.6}Ga_{0.4}As (curve 1012, 1014), Ge (curves 1016, 1018) and bulk Si (curves 1020, 1022). The corresponding ionization coefficient ratios are shown in FIG. 10(C).

The position dependent ionization coefficients, a(z) and b(z), are defined as

$$a ( z ) = \frac{1}{n ( z )} \frac{d {n}_{e} ( z )}{d z} and b ( z ) = \frac{1}{p ( z )} \frac{d {p}_{h} ( z )}{d z} \qquad ( 3 )$$

where n(z) and p(z) are the concentrations of electrons and holes at position z and dnₑ(z)/dz and dpₕ(z)/dz are the rates of increase of these quantities due to electron and hole ionization, respectively, in the directions of transport of those carriers, as obtained from the simulation.

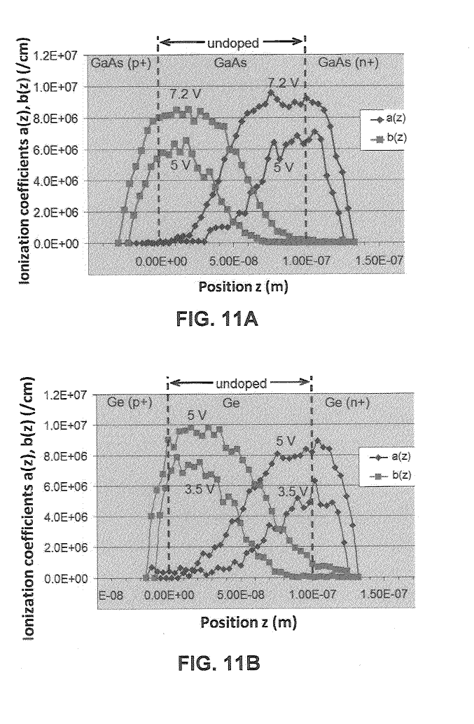

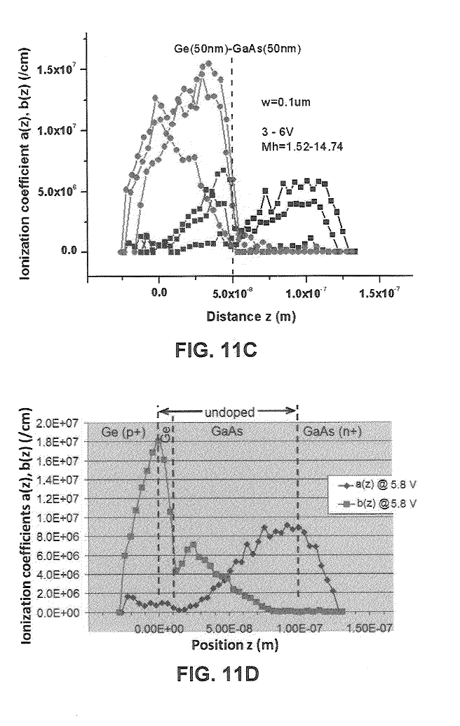

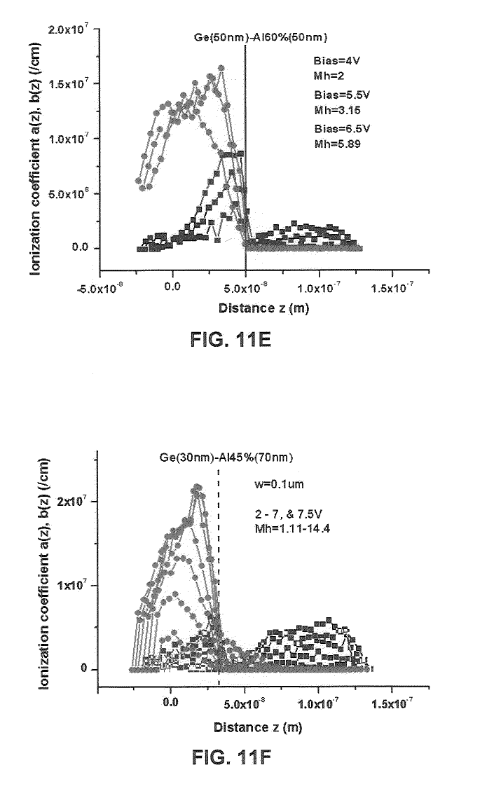

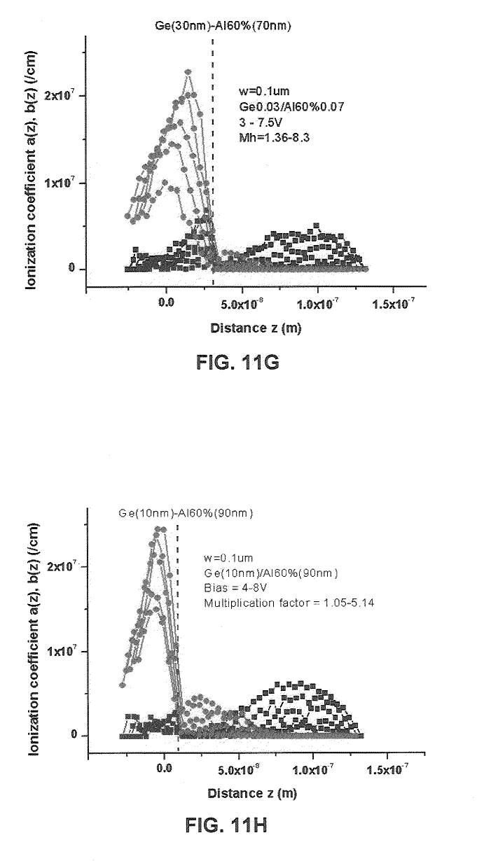

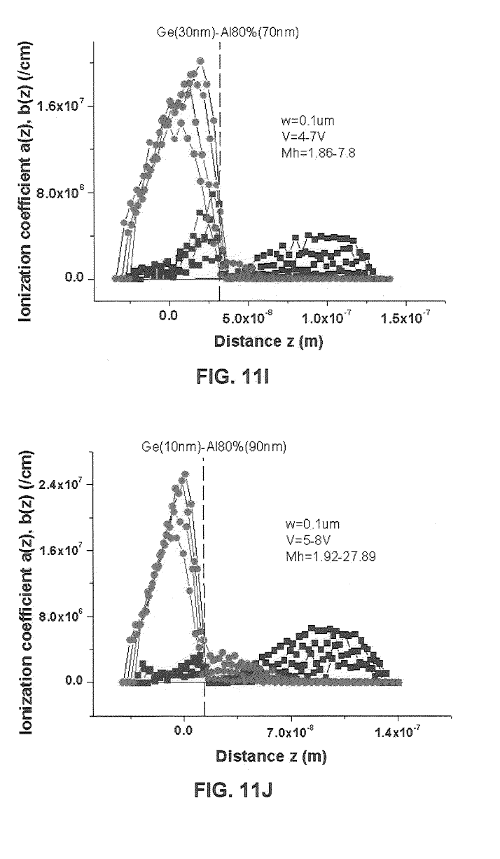

The simulated results are presented in FIGS. 11(A)-(J) for different heterojunction photodiodes according to example embodiments, where the i-region thickness for the respective devices is 0.1 μm.

From the results in FIGS. 11(A) to (J), it was confirmed that the feedback from ionization of the opposite carrier (electron) is greatly suppressed in the AlₓGa₁₋ₓAs portion of the Ge—AlₓGa₁₋ₓAs undoped regions, resulting in the advantageous large difference in ionization coefficients as shown in FIGS. 10(A) to (C).

Example embodiments of the present invention can provide a low noise Ge—AlₓGa₁₋ₓAs—GaAs heterojunctions APDs covering a wide detection range of about 400 nm-1700 nm. The Ge—GaAs—AlₓGa₁₋ₓAs APDs have low excess noise, at 850, 1310 and 1550 nm, owing to the suppressed ionization of the opposite carrier. Example embodiments of the present invention advantageously provide a low noise APD operating at a wavelength longer than 1100 nm, in particular at technologically important wavelengths of 1310 and 1550 nm. The APDs of example embodiments exhibit similar low noise characteristic as in Si APD.

Example embodiments of the present invention can also provide photodetectors that are sensitive to both 850 and 1310 nm wavelengths, for use in optical interconnects for consumer application (active optical cables, Intel's light peak) or fiber to the home communication systems. These applications deal with weak optical signals in the range of μW and hence low noise APDs of example embodiments operating at these wavelengths will be very useful to detect and amplify the signals.

Example embodiments of the present invention advantageously provide avalanche photodiodes that can detect and have high responsivity at 850 nm and 1100-1600 nm and with excess noise similar to that of Si.

Example embodiments of the present invention allow the same Ohmic contact for p-type Ge and n-type GaAs in the designed structure, and thereby can provide simplified processing steps and significant cost savings.

Example embodiments of the present invention can be used in applications for data- and tele-communications, single photon detection in secure communication system/Single photon avalanche diode (SPAD) and as detectors in active optical cables/optical USB.

What is claimed is:

1. An avalanche photodiode structure comprising:
a Ge doped region having a first polarity;
a GaAs doped region having a second polarity opposite to the first polarity; and
an undoped region between the Ge doped region and the GaAs doped region forming a heterojunction;
wherein the undoped region comprises Ge and AlₓGa₁₋ₓAs.

2. The avalanche photodiode structure as claimed in claim 1, wherein the undoped region comprises Ge, GaAs and AlₓGa₁₋ₓAs.

3. The avalanche photodiode structure as claimed in claim 1, wherein the undoped region comprises a GaAs—AlₓGa₁₋ₓAs graded composition portion.

4. The avalanche photodiode structure as claimed in claim 3, wherein the GaAs—AlₓGa₁₋ₓAs graded composition portion extends between a Ge layer of the undoped region and a AlₓGa₁₋ₓAs layer of the undoped region.

5. The avalanche photodiode structure as claimed in claim 3, wherein the GaAs—AlₓGa₁₋ₓAs graded composition portion extends between a Ge layer of the undoped region and a AlₓGa₁₋ₓAs portion of the GaAs doped region.

6. The avalanche photodiode structure as claimed in claim 1, wherein the GaAs doped region comprises an n-type light absorption layer for 850 nm and the Ge doped region comprises a p-type absorption layer for 1310 and 1550 nm.

7. The avalanche photodiode structure as claimed in claim 1, wherein the heterojunction has a p-i-n configuration disposed on one of a group consisting of a Ge p-type substrate, a GaAs n-type substrate, a Ge-on-insulator p-type substrate or GaAs-on-insulator n-type substrate.

8. The avalanche photodiode structure as claimed in claim 1, wherein the undoped region is <0.3 μm thick.

9. The avalanche photodiode structure as claimed in claim 8, wherein the undoped region is <0.2 μm thick.

10. The avalanche photodiode structure as claimed in claim 1, wherein 1≧x≧0.2.

11. The avalanche photodiode structure as claimed in any one of claim 10, wherein 1≧x≧0.4.

12. The avalanche photodiode structure as claimed in claim 1, wherein an AlₓGa₁₋ₓAs undoped layer thickness (t_{AlxGa1-xAs})>an Ge undoped layer thickness (t_{Ge}).

13. The avalanche photodiode structure as claimed in claim 2, wherein an AlₓGa₁₋ₓAs undoped layer thickness (t_{AlxGa1-xAs})>a combined thickness of a Ge undoped layer and a GaAs undoped layer it (t_{Ge}+t_{GaAs}).

14. The avalanche photodiode structure as claimed in claim 3, wherein an AlₓGa₁₋ₓAs undoped layer thickness (t_{AlxGa1-xA})>a combined thickness of an Ge undoped layer plus an GaAs—AlₓGa₁₋ₓAs undoped graded layer (t_{Ge}+t_{GaAs—AlGaAs}).

15. The avalanche photodiode structure as claimed in claim 3, wherein an GaAs—AlₓGa₁₋ₓAs undoped graded composition layer thickness (t_{GaAs—AlxGa1-xAs})>an Ge undoped layer thickness (t_{Ge}).

16. The avalanche photodiode structure as claimed in claim 1, having a detection range covering about 400-1700 nm in wavelength.

17. The avalanche photodiode structure as claimed in claim 1, wherein the GaAs doped region comprises a graded AlₓGa₁₋ₓAs/GaAs n+ layer at an undoped-n+ interface.

18. The avalanche photodiode structure as claimed in claim 1, further comprising ohmic contacts for the Ge doped region and the GaAs doped region respectively.

19. The avalanche photodiode structure as claimed in claim 18, wherein the ohmic contacts to the Ge doped region and the GaAs doped region respectively are formed from substantially the same material.

20. The avalanche photodiode structure as claimed in claim 2, wherein a GaAs layer interfacing to a Ge layer of the undoped region comprises indium.

21. The avalanche photodiode structure as claimed in claim 20, wherein the GaAs layer interfacing to the Ge layer of the undoped region comprises 1% indium (In_{0.01}Ga_{0.99}As).

22. A device comprising an avalanche photodiode structure as claimed in claim 1.

23. A method of fabricating an avalanche photodiode structure, the method comprising the steps of:
providing a Ge doped region having a first polarity;
providing a GaAs doped region having a second polarity opposite to the first polarity; and
providing an undoped region between the Ge doped region and the GaAs doped region forming a heterojunction;
wherein the undoped region comprises Ge and AlₓGa₁₋ₓAs.

24. The method as claimed in claim 23, further comprising forming ohmic contacts to the Ge doped region and the GaAs doped region respectively from substantially the same material.
